(19) United States
(12) Patent Application Publication
(10) Pub. No.: US 2009/0084317 A1
(43) Pub. Date: Apr. 2, 2009

(54) ATOMIC LAYER DEPOSITION CHAMBER AND COMPONENTS

(75) Inventors: Dien-Yeh Wu, San Jose, CA (US); Schubert S. Chu, San Francisco, CA (US); Paul Ma, Santa Clara, CA (US); Jeffrey Tobin, Mountain View, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/864,053

(22) Filed: Sep. 28, 2007

(51) Int. Cl. C23C 16/00

(52) U.S. Cl. 118/728

(57) ABSTRACT

An atomic layer deposition chamber comprises a gas distributor comprising a central cap having a conical passageway between a gas inlet and gas outlet. The gas distributor also has a ceiling plate comprising first and second conical apertures that are connected. The first conical aperture receives a process gas from the gas outlet of the central cap. The second conical aperture extends radially outwardly from the first conical aperture. The gas distributor also has a peripheral ledge that rests on a sidewall of the chamber.

### BACKGROUND

Embodiments of the present invention relate to an atomic layer deposition chamber and its components.

In the fabrication of integrated circuits and displays, an atomic layer deposition (ALD) chamber is used to deposit an atomic layer having a thickness on the order of atoms onto a substrate. Typically, the ALD chamber comprises an enclosure into which a process gas is introduced and an exhaust to exhaust and control the pressure of the process gas in the chamber. In one type of atomic layer deposition process, a first process gas introduced into the chamber to form a thin layer of gas molecules adsorbed onto the substrate surface; and thereafter, a second process gas is introduced to react with the adsorbed layer of gas molecules to from an atomic layer on the substrate. The process gases can include conventional pressurized gases or carrier gases to transport organic or other molecules into the chamber. Typically, the chamber is purged between the delivery of each process gas. The purge can be continuous in which a continuous flow of carrier gas is provided to the chamber or pulsed in which a discontinuous or pulsed flow of carrier gas is provided.

Conventional substrate processing chambers used for CVD or PVD processes are being converted to ALD chambers because ALD processes are being increasingly used to deposit atomic layers on the substrate. However, conventional chambers do not always provide the sufficiently high levels of gas distribution, plasma, or thermal uniformity, required for ALD processes. For example, ALD chambers use particular types of gas distributors, shields, and exhaust components, all of which cooperate to provide more uniform delivery to, and removal of, process gas species from across the substrate surface. ALD converted chambers can also require specific components for different types of ALD processes, for example, thermal or plasma enhanced ALD (PEALD) processes. In thermal ALD, heat is provided to cause a chemical reaction between two or more reactants adsorbed onto a substrate surface. In thermal ALD, additional chamber components may be required to heat or cool the substrate or other chamber surfaces. PEALD processes require gas energizers to energize the process gas, and its components are designed to withstand etching by the energized process gas. Thus it is further desirable to have chamber conversion kits that can easily alter conventional chambers to ALD chambers.

The ALD chamber components also need to provide good gas distribution uniformity across the substrate without inducing other adverse effects. For example, in plasma assisted ALD, providing a process gas stream that flows directly onto the substrate surface increases the possibility of adversely etching the substrate surface. Thermal ALD processes provide reduced gas efficiency when process gas species react with internal chamber surfaces instead of the substrate. Further, conventional showerhead gas distributors often provide process gas on the central region of the substrate at higher concentrations that at peripheral region of the substrate. It is also difficult to obtain uniform pressures of process gas species across the substrate surface during deposition. It is also sometimes desirable for the ALD chamber to be effectively purged between sequential process gas steps.

Thus there is a need for ALD process kit and chamber components that can be used to retrofit conventional chambers. There is also a need for ALD chamber components that provide better gas, temperature and pressure uniformity across the substrate, while also allowing rapid purging of process gas.

### DRAWINGS

The following description, claims, and accompanying drawings, illustrate exemplary embodiments of different features which can be used by themselves, or in combination with other features, and should not be limited to the exemplary versions shown in the drawings:

FIG. 1 is a schematic sectional side view of an embodiment of a thermal ALD chamber;

FIGS. 2A and 2B are a cross-sectional top view and a top planar view of an ceiling plate of the chamber lid of the ALD chamber of FIG. 1, showing a heat transfer fluid conduit having a rectangular shape;

FIG. 3 is a perspective view of a chamber liner that can be used in the ALD chamber of FIG. 1;

FIG. 4 is an exploded perspective view of an exhaust shield assembly of the ALD chamber of FIG. 1;

FIG. 5 is a schematic sectional side view of an embodiment of a PEALD chamber;

FIG. 6A is a schematic bottom view of a chamber lid of the PEALD chamber of FIG. 5, the chamber lid having a gas distributor with a fan-type insert;

FIG. 6B is a cross-sectional perspective view of the fan-type insert of FIG. 6A;

FIG. 7A is a perspective view of a chamber liner of the PEALD chamber of FIG. 5;

FIG. 7B is a cross-sectional view of the chamber liner of FIG.7A; and

FIG. 8 is a perspective view of a plasma screen of the PEALD chamber of FIG. 5.

### DESCRIPTION

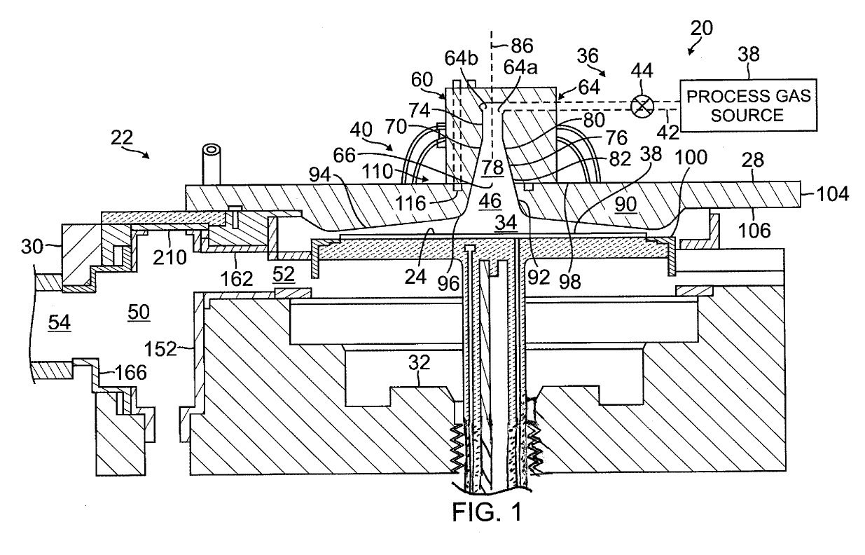

An embodiment of a substrate processing apparatus 20 comprising an atomic layer deposition (ALD) chamber 22 is shown in FIG. 1. The chamber 22 is suitable for thermal ALD processes for deposition of an atomic layer on a substrate 24 resting on a substrate support 26. In thermal ALD processes, process gas molecules adsorbed onto a substrate 24 are heated to temperatures sufficiently high to form an atomic layer on the substrate 24. Suitable thermal ALD temperatures can be, for example, from about 120° C. to about 450° C. The chamber 22 is suitable for processing substrates 24 such as semiconductor wafers, however, the chamber 22 can be adapted to process other substrates 24, such as for example, flat panel displays, polymer panels, or other electrical circuit receiving structures, as would be apparent to those of ordinary skill in the art. The apparatus 20 can also be attached to a platform (not shown) that provides electrical, plumbing, and other support functions for the chamber 22, and which can also be part of a multi-chamber platform system such as, for example, the DaVinci or Endura II platform, available from Applied Materials Inc., Santa Clara, Calif.

Generally, the chamber 22 is enclosed by a ceiling 28, sidewall 30, and bottom wall 32. The substrate support 26 extends through the bottom wall 32 to support the substrate 24 on a substrate receiving surface 33. The substrate support 26 together with the sidewall 30 defines a process zone 34 in which process gas is provided to process the substrate 24. In operation, process gas is introduced into the chamber 22 through a gas supply 36 that includes a process gas source 38 and gas distributor 40. The gas distributor 40 may comprise one or more conduits 42 to provide gas having a gas supply valve 44 therein, and a gas outlet 66 46 to release the process gas into the process zone 34 of the chamber 22. For ALD processes, the process gas source 38 can be used to supply different process gases that can each contain a single gas or a mixture of gases, a carrier gas and transported molecule, or a purge gas which may also be the carrier gas. Spent process gas and process byproducts are exhausted from the chamber 22 through an exhaust system 50 which may include an exhaust port 52 that receives spent process gas from the process zone 34 and delivers the gas to an exhaust conduit 54, and a throttle valve and exhaust pumps (not shown) to control the pressure of process gas in the chamber 22.

The gas distributor 40 comprises a central cap 60 having one or more gas inlets 64a,b, a gas outlet 66, and a gas passageway 70 between the gas inlet 64 and gas outlet 66. The gas inlets 64a,b are offset from one another in the horizontal plane and positioned around a circumference of the gas passageway 70. The offset gas inlets 64a,b provide individual gas streams that cooperate in the gas passageway 70 to achieve a spiraling gas flow from the inlets 64a,b to the outlet 66. In one version, the gas inlets 64a,b can be offset by being positioned at a separation angle of at least about 45 degrees, for example, about 180 degrees. The top portion 74 of the gas passageway 70 in the cap 60 is cylindrical. The bottom portion 76 of the gas passageway 70 comprises a conical passageway 78 which gradually opens outward in the downward gas flow direction with the radius of the inner diameter of the conical passageway 78 increasing from a first diameter at an upper region 80 to a second larger diameter at a lower region 82 about the outlet 66 of the cap 60. In one version, the first diameter is less than about 2.6 cm and the second diameter is at least about 3 cm. For example, the first diameter can be from about 0.2 cm to about 2.6 cm and the second diameter can be from about 3 cm to about 7.5 cm. The conical passageway 78 can also have a surface that is inclined relative to the vertical axis at an angle of from about 5° to about 30° or more typically about 11°.

When process gas is injected into the cap 60 through the offset gas inlets 64a,b, the simultaneously injected gas streams spin about a vertical axis 86 through the conical passageway 78 in a vortex motion to produce a spiral flow of gas heading downwards from the inlets 64a,b to the outlet 66. Advantageously, the angular momentum of the spiraling gas causes the gas to sweep the surface of the conical passageway 78. Also, the gradual increase in diameter of the conical passageway 78 from the first diameter to the second diameter, produces an increasing volume of the gas, which results in a corresponding increase in the width of the gas vortex and a gradual reduction in gas pressure and temperature, both of which are desirable because they inhibit condensation of the precursor gas and reduce the vertical speed of the gas onto the substrate 24. Further, the rotational energy and angular momentum of the process gas about the vertical axis 86 of the conical passageway 78 decreases as the process gas descends along the passageway. The conical passageway 78 is bell shaped to allow the process gas vortex to fan out as it enters the chamber 22 and thereby providing a better distribution of the process gas directly above the substrate 24.

The central cap 60 rests on a shaped ceiling plate 90 which in one version is funnel-shaped. The shaped ceiling plate 90 serves as a chamber lid, and has interconnected first and second conical apertures 92,94. The first conical aperture 92 receives a process gas from the gas outlet 66 and has a first diameter, and the second conical aperture 94 releases the process gas and has a second diameter that is larger than the first diameter. Each of the conical apertures 92, 94 are gradually outwardly tapered with a continuously increasing diameter. In one version, the ceiling plate cap 90 is composed of aluminum such as for example aluminum alloy.

The first conical aperture in 92 the shaped ceiling plate 90 connects to the outlet 66 of the central cap 60 and has a narrower first diameter at an interface surface 98 between the ceiling plate 90 and the central cap 60, which gradually increases to a larger diameter at the segment joint 96 that joins to the second conical aperture 94. In one version, the gradually tapered surface of the first conical aperture 92 comprises a conical surface with an inclination angle of from about 50° to about 30° relative to the vertical axis. The segment joint 96 comprises a rounded edge and provides a gradual transition between the slopes of the first and second conical apertures 92, 94. The second conical aperture 94 extends radially outward with an increasing diameter from a first diameter at the segment joint 96 to a second larger diameter above an outer perimeter 100 of the substrate support 26. The surface of the second conical aperture 94 has a conical surface with an inclination angle of from about 1° to about 15° relative to the vertical axis.

The shaped ceiling plate 90 also has a peripheral ledge 104 that extends radially outwardly out from the gas distributor 40 and above the outer perimeter 100 of the substrate support 26. The lower surface 106 of the peripheral ledge 104 is substantially horizontal to allow the peripheral ledge 104 to rest about the sidewall 30 of the chamber 22 to support the ceiling plate 90 above the process zone 34. The peripheral ledge 104 has a stepped down height with an intermediate step 108 that smoothly curves upwards from the second conical aperture 94 to the peripheral ledge 104.

The shaped conical passageway 78 through the central cap 60, and the first and second conical apertures 92,94 of the ceiling plate 90, also allow process gas or purge gas to pass through with minimum flow resistance and provide good distribution across a surface of the substrate 24. The conical passageway 78 increases in diameter as the gas descends into the chamber 22. The width of the spirally descending process gas vortex likewise increases to provide a high velocity gas flow. The rotational energy and angular momentum of the process gas about the vertical axis 86 of the conical passageway 78 decreases as the process gas descends along the passageway. The portion of the gas passageway within the ceiling plate 90 has a diameter that increases between the top and bottom of the ceiling plate 90. Thus, the entire gas passageway through the cap 60 and ceiling plate 90 is bell shaped to allow the process gas vortex to fan out as it enters the chamber 22, thereby uniformly distributing the process gas into the process zone 34 of the chamber 22 directly above the substrate 24.

The gas distributor 40 can also comprise a temperature regulating system 110 which includes heating or cooling elements and temperature sensors. The ceiling mounted gas distributor 40 takes up much of the surface area in the region of the process zone. Thus it is desirable to control the temperature of the gas distributor 40 to control its effect on the process gas about the substrate 24. If the gas distributor 40 is too hot, for example, the process gas can react at its surfaces to deposit material at these surfaces instead of on the substrate 24. Alternatively excessive cooling of the gas distributor 40 can cause the process gas to be excessively cool in temperature when it reaches the substrate 24. Thus, it is desirable to control the temperatures of the gas distributor 40 to maintain temperatures that provide optimum delivery of the process gas to the substrate 24.

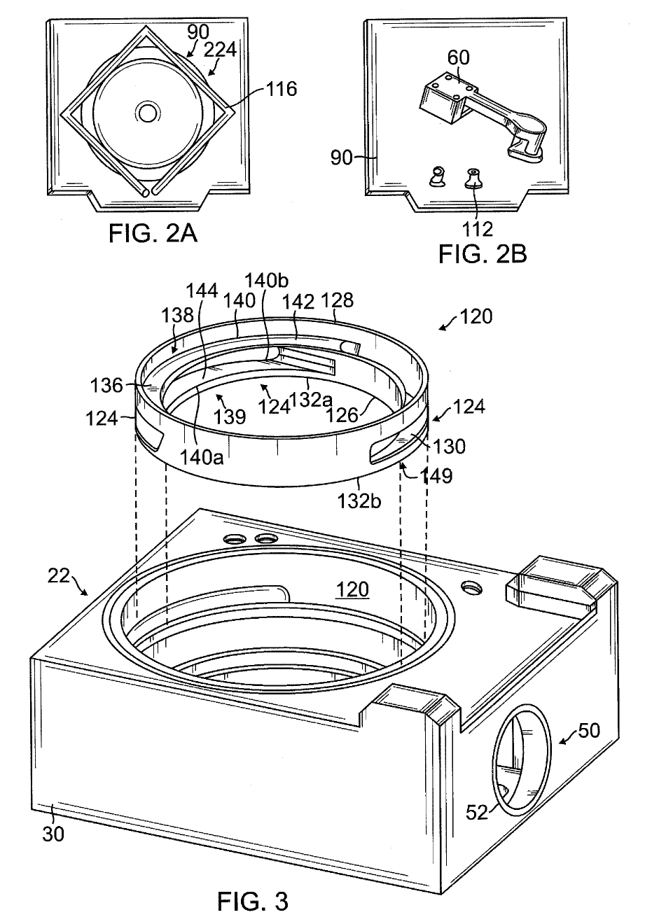

In one version, the temperature regulating system 110 comprises heat transfer fluid conduits 112 that contact the gas distributor 40, for example, contacting the cap 60, the ceiling plate 90, or both. The temperature regulating system 110 can include a fluid conduit 116 for passing heat transfer fluid therethrough to remove or add heat to the process gas. In one version, the fluid conduit 116 comprises a channel that is machined through the ceiling plate 90, as shown in FIG. 2A. This allows the fluid conduit 116 to also control the temperature of the process gas as it passes through the gas passageway 70 which extends through the central cap 60 and the ceiling plate 90. For example, when the process gas passing through this region rapidly changes in temperature because of expansion of the gas arising from the different volumes of the conical passageway 78 and first conical aperture 92, the change in gas temperature can be regulated by passing a heat transfer fluid maintained at a desired temperature differential through the fluid conduit 116. The heat transfer fluid exchanges heat with the process gas passing through the gas distributor 40 to regulate its temperature. The temperature of the heat transfer fluid is regulated using a conventional heat exchange system (not shown) external to the chamber 22, comprising for example, a pump connecting a fluid reservoir comprising a heat transfer fluid such as deionized water, to the fluid conduits 116 and including a heating or refrigeration system to heat or cool the fluid in the fluid conduit 116.

The process gas passed into the chamber 22 is contained about the processing region of a substrate 24 by a chamber liner 120 which at least partially covers a sidewall 30 of the chamber 22 to encircle the process zone 34. The chamber liner 120 serves to shield the walls of the chamber 22 from the process gas and also to confine the process gas to the region above the substrate 24. The chamber liner 120 is typically shaped to at least partially conform to the chamber sidewall 30. The chamber liner 120 also has gas openings 124 to allow process gas to flow therethrough from the process zone 34 to the exhaust port 52. The chamber liner 120 can be made from a metal, such as aluminum or a ceramic.

A chamber liner 120 suitable for the chamber 22 comprises first annular band 126 having a first diameter and a second annular band 128 having a second diameter, as shown in FIG. 2A. The second annular band 128 is sized larger than diameter of the first annular band 126. For example, the second diameter of the second annular band 128 can be at least about 2 cm larger than the first diameter of the first annular band 126. The first annular band 126 also comprises a first height and the second annular band 128 comprises a second height that is larger than the first height, for example, the second annular band 128 can have a second height that is at least 2 cm larger than the first height of the first annular band 126. In one version, the first annular band 126 has a first diameter of from about 12 inches to about 15 inches and a first height of from about 1.5 inches to about 2.5 inches; and the second annular band 128 has a second diameter of from about 15 inches to about 18 inches and a first height of from about 2.5 inches to about 4 inches.

The first and second annular bands 126,128 of the chamber liner 120 are structurally joined together at their bottom edges 132a,b by a radial flange 130 which is circular in shape. The radial flange 130 serves to hold the first and second annular bands 126,128 in a spaced apart gap in the radial direction. The radial flange 130 can be sized to provide a radial gap of at least about 38 mm, for example, from about 25 to about 50 mm. A radial ledge 136 further joins the midsection 138 of the second annular band 128 to the top edge 140 of the first annular band 126 of the chamber liner 120. The radial ledge 136 provides additional structural integrity to the chamber liner 120. The radial ledge 136 extends across a portion of the inner circumference of the chamber liner 120, for example, to cover from about 0 to about 1800 of the inner circumference. As a result, an open gap region is provided across the remaining portion of the inner circumference to provide easier flow and passage of process gas through the chamber liner 120.

The chamber liner 120 also has a first encased opening 139 which allows process gas to flow through the first and second annular bands 126, 128 from the process zone 34 to the exhaust port 52. The first opening 139 is formed by the alignment of a first slot 140a extending therethrough the first annular band 126 and a second slot 140b passing through the second annular band 128 which is aligned to the first slot 140a of the first annular band 126. The aligned slots 140a,b are surrounded by a flat top wall 142 and bottom wall 144 to form an encased first opening 139. In one version, the first and second slots 140a,b comprise rectangles with rounded corners. For example, the rectangles can each have a length of from about 12 to 18 inches and a height of from about 0.75 to 3 inches. The aligned slots 140a,b allow the passage of process gas species through the chamber liner 120 with reduced erosion of the corners and edges of the slots 140a,b. The chamber liner 120 can also have an additional second opening 149 in the first annular band 126 which opens to the exhaust port 52. The first and second openings 139, 149 facilitate the passage of gas through the chamber liner 120. In one version, the first opening 139 allows passage of substrate 24 through the chamber liner 120, for example by robot transport of the substrate 24 to and from the chamber 22.

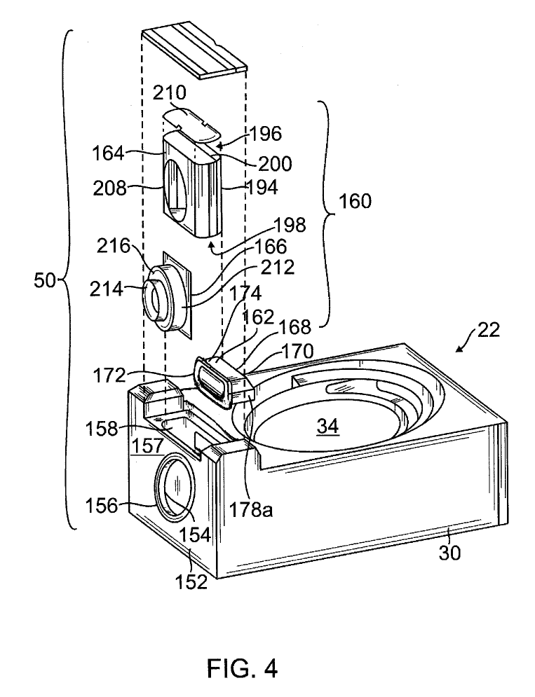

The chamber 22 also has an exhaust port 52 that receives spent process gas from the process zone 34 after the process gas passes over the substrate surface to exhaust the process gas from the chamber 22 and delivers the gas to an exhaust conduit 54. The exhaust port 52 is provided in a hollow exhaust block 152 which forms part of the sidewall 30 of the chamber. The hollow exhaust block 152 comprises a rectangular inlet port 154 on an inner wall 155, a circular outlet port 156 on an outer wall 157, and a rectangular channel 158 therebetween, as shown in FIG. 4. The hollow exhaust block 152 is exposed to hot reactive process gas species gas that results in the deposition of process residue material on it interior surfaces. The accumulation of such process residue deposits is undesirable as these deposits flake off from the interior surfaces over time cause substrate contamination. The accumulation of such process gas deposits onto the exhaust surfaces can be fixed by cleaning out the interior surfaces of the exhaust block 152 but this requires dismantling of the chamber 22 as the exhaust block is often an integral part of the chamber 22, which is time consuming and results in excessive chamber downtime. Problems also arise when the composition of the process gas used in the chamber 22 is changed or other because the deposits already accumulated onto the interior surfaces of the exhaust block 152 can react with the new gas species in an undesirable manner.

Thus, an exhaust shield assembly 160 is provided to protect, and provide easily replaceable and removable surfaces, around the exhaust port 52 and in the exhaust block 152 of the chamber 22. An exemplary embodiment of an exhaust shield assembly 160, as shown for example in FIG. 4, comprises an assembly of component structures that cooperate together to provide good flow of process gas through this region while still allowing rapid removal and disassembly of the exhaust shield assembly 160 for cleaning or replacement of the component structures. The exhaust shield assembly 160 can be easily removed and cleaned or replaced when excessive deposits form on their surfaces. Further, after use in a set number of process cycles, or a change in process gas composition, the removable exhaust shield assembly 160 can be discarded and replaced with a fresh exhaust shield assembly, to provide a consumable exhaust lining system. After removable from the chamber 22, the exhaust shield assembly 160 can also be cleaned by rinsing with solvents and reused.

In one version, the exhaust shield assembly 160 comprises an inner shield 162, pocket shield 164, and outer shield 166 and cover shield 210. The inner shield 162 comprises an enclosed rectangular band 168 having a perimeter 170 defined by upper and lower planar walls 174,176 that are substantially parallel to one another and which are connected by arcuate end portions 178a,b. In one version, the planar walls 174,176 are separated by at least about 4 cm. A cross-sectional profile of the rectangular band 168 is shaped like a rectangle with rounded corners. However, the arcuate end portions 178a,b of the band 168 can also be cylindrical, multi-radius curved, or even substantially flat. The inner shield 162 is positioned on an inner wall 180 of a hollow exhaust block 152 in the chamber 22 and the enclosed rectangular band 168 is sized to fit over the rectangular inlet port 154 in the hollow exhaust block 152.

The inner shield 162 also comprises a planar frame 172 extends perpendicularly beyond the perimeter of the rectangular band 168. The planar frame 172 is positioned at an outer end 190 of the inner shield 162. The planar frame 172 is placed flush against a matching rounded rectangular hole in the pocket shield 164. In one version, the planar frame 172 extends outward beyond the perimeter of the band by from about 3 to about 14 cm. The planar frame 172 can be welded or brazed to the perimeter 170 of the rectangular band 168 and is usually made from the same material, that is, a sheet of aluminum.

The pocket shield 164 comprises a tubular encasing 194 having a top end 196 and a bottom end 198. The tubular encasing 194 has opposing first and second surfaces 200, 202 which enclose a rectangular hollow sleeve. The first planar surface 200 has an inner rectangular cutout 206 that fits the rectangular band 168 of the inner shield 162 so that process gas can flow thorough this passageway. The second planar surface 202 has an outer circular cutout 208 which fits onto the outer shield 166. A cover plate 210 covers and closes off the top end 196 of the tubular encasing 194. The bottom end 198 of the pocket shield 164 has a well 212 which is adapted for fitting within the exhaust block 152. In one version the well 212 is oval-shaped. The pocket shield 164 is sized to fit inside the rectangular channel 158 of the hollow exhaust block 152.

The outer shield 166 comprises first and second cylinders 212, 214 that are joined to one another. In the version shown, the first cylinder 212 is sized larger than the second cylinder 214. The dimensions of the first and second cylinders 212, 214 are determined by the chamber geometry because the outer shield 166 is adapted to be positioned to be flush against the outer wall 157 of the hollow exhaust block 152. The second cylinder 214 of the outer shield 166 is sized to fit the circular outlet port 158 of the hollow exhaust block 152. In one version, the outer shield 166 has a height of from about 5.5 inches to about 7 inches, and a width of from about 5.5 inches to about 8 inches, and a depth of from about 1.4 to about 4 inches. A planar member 216 is attached to the second cylinder 214 and extends perpendicularly beyond the second cylinder. In one version, the planar member 216 extends beyond the edge of the second cylinder 214 by from about 0.5 to about 1.5 inches.

In one version, the inner shield 162, pocket shield 164, outer shield 166 and cover plate 210, are all made from a metal, such as for example, aluminum, stainless steel, or titanium. In one version, the exhaust shield assembly 160 is stamped and pressed out of aluminum sheets having a thickness of about 0.06 inches. In addition, the surfaces of the shield components can comprise bead-blasted surfaces for better adherence of process residues. In one version, the surfaces have a surface roughness of about 40 to about 150 microinches, or even about 54 microinches. The surface roughness can also be obtained by wet sanding with a slurry comprising particles of from about 40 to about 125 microns in diameter or by dry sanding with a sandpaper comprising 120 to 400 grit.

When the exhaust shield assembly 160 is installed in the hollow exhaust block 152, the components of the shield assembly 160 tightly fit against and contact each other. The inner shield 162 is in contact with the pocket shield 164, and the planar frame 172 of the inner shield 162 is aligned with the slot of the pocket shield 164. The surface of the outer shield 166 is in contact with the first planar surface of the pocket shield 164 and the cover plate 210 covers the pocket shield 164. It is not necessary for the shield components of the exhaust shield to form a gas tight seal with each other, but the components should have good contact with each other to reduce leakage of process gas from the exhaust block 152.

### Plasma ALD Chamber

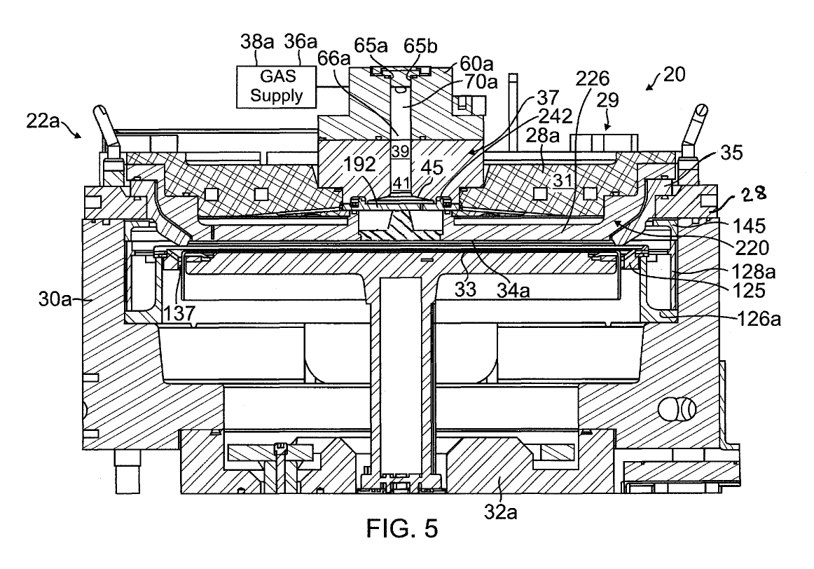

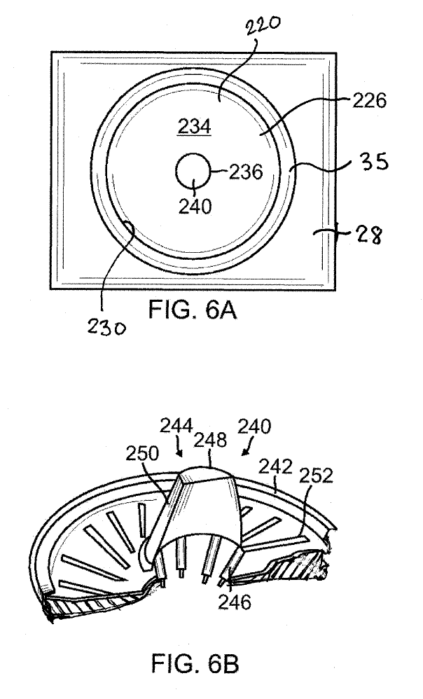

Another embodiment of the substrate processing apparatus 20 comprises an ALD chamber 22a suitable for plasma ALD processes, as shown in FIG. 5. The chamber 22a has a lid 29 that is adapted to provide good temperature characteristics for plasma ALD and can have heat exchange elements for cooling or heating of the chamber lid 29a such as, for example, a water-cooled ceiling plate 31 as shown in FIG. 5. The apparatus 20 can also comprise remote or in-situ gas energizer elements, such as for example a remote gas energizer (model # ASTRO, available from MKS Instruments, Inc., Wilmington, Mass.), or electrical connectors, power supply and electrodes mounted in or about the chamber for in-situ plasma generation. In some chambers, a metal element of the chamber lid 29 is used as a process electrode. Also, one or more insulation rings 35 can be provided between the chamber wall and ceiling to provide thermal or electrical insulation between the chamber components. A process gas supply 38a or components of a process gas supply 38a can be mounted on the chamber lid 29 and can include pneumatic valves, a process gas source 36a or various tubes and channels for delivery of controlled levels of process and purge gasses to the process chamber 22a during processing.

In the chamber shown in FIG. 5, the gas distributor 40a comprises a central cap 60a, a ceiling insert 37 and a showerhead 220 that fits into a bottom surface of the chamber lid 29. The central cap 60a has one or more gas inlets 65a,b, a gas outlet 66a, and a gas passageway 70a between the gas inlet 65 and gas outlet 66a. The gas inlets 65a,b are offset from one another in the horizontal plane and positioned around a circumference of the gas passageway 70a. The offset gas inlets 65a,b provide individual gas streams that cooperate in the gas passageway 70a to achieve a spiraling gas flow from the inlets 65a,b to the outlet 66a. In one version, the gas inlets 65a,b can be offset by being positioned at a separation angle of at least about 60 degrees, for example, about 180 degrees. The gas passageway 70a in the cap 60a is cylindrical and has a substantially uniform diameter through its length.

The cap 60a rests on a ceiling insert 37 having and a conical passageway 43 therethrough for passage of process gas. The ceiling insert 37 comprises ceramic or quartz and serves to electrically and thermally insulate the process gasses from the other components of the chamber lid 29. The inlet 39 of the ceiling insert 37 receives process gas from the outlet 66a of the central cap 60a. The conical passageway 43 has a lower portion 45 that opens outward in the downward flow direction such that the diameter of the passageway 43 increases across the lower quarter of the ceiling insert 37. The passageway 43 terminates in an outlet 41 having a diameter that is about twice the diameter of the inlet 39. This sudden opening of the passageway 43 allows adaptation to the larger receiving surface of the plasma screen 192.

When process gas is injected into the cap 60a through the offset gas inlets 65a,b, the simultaneously injected gas streams spin about a vertical axis 86a through the passageway 70a in a vortex motion to produce a spiral flow of gas heading downwards from the inlets 65a,b to the outlet 41 of the ceiling insert 37. Advantageously, the spiral flow mixes the gas and results in a more homogeneous mixture of gas at the outlet 41.

The vortex of process gas spirals from the outlet 41 of the ceiling insert 37 to a plasma screen 192. The plasma screen 192 comprises an annular plate 222 having a plurality of holes 224 which are spaced apart and distributed across the plasma screen 192 to screen the center of the channel from direct plasma passage. In one version a central region 232 of the plasma screen 192 has no holes therethrough, which prevents direct view of the RF electrodes. The number of holes 224 in the plasma screen 192 can be from about 50 to about 400, and in one version, from about 150 to about 170. In one version, the holes 224 have a diameter of from about 0.1 cm and about 0.3 cm. The plasma screen 192 can also comprise a shaped peripheral lip 238 and raised circular band 242 about the holed region of the screen 220, as shown in FIG. 8. The peripheral lip 238 and circular band 242 are shaped to form a seal with the ceiling insert 37. In one version, the plasma screen 192 comprises a ceramic. The plasma screen 192 is annular in shape and has a thickness of from about 0.15 inches to about 1 inch.

The plasma screen 192 delivers process gas to a showerhead 220 gas distributor. The showerhead 220 comprises a plate 226 having a plurality of holes 228 which are spaced apart and distributed across the showerhead 220 to evenly distribute the process gas across the substrate surface. The number of holes 228 in the showerhead 220 can be from about 100 to about 10,000, and in one version, from about 500 to about 2500. In one version, the holes 228 have a diameter of from about 0.01 and about 0.1 inches. In one embodiment, the holes 228 are shaped and sized to decrease in diameter between the upper surface and the lower surface of the plate 226. This provides a reduction in back flow within the plate 226. In one version, the showerhead 220 comprises a metal such as aluminum, steel, or stainless steel. The showerhead 220 is annular in shape and a thickness of from about 0.3 to about 2.5 inches.

The showerhead 220 comprises a peripheral region 230 that rests on an isolator 113 above the chamber sidewall 30a and a central region 234 with a hole 236 bored through the center of the showerhead 220 to receive a gas distributor insert 240. The gas distributor insert 240 comprises an annular plate that is sized with a diameter sufficiently large to fit into the showerhead 220. The annular plate has a central region and a peripheral region. The central region of the insert 240 comprises a protrusion 244 having a flat annular top surface 248 and a side wall 250 that extends outward and downward from the flat annular surface 248 to the surface of the body region. In one version the flat annular surface 248 of the insert 240 contacts the central region of the plasma screen 192. In one version, the annular plate of the gas distributor insert 240 is composed of a metal, such as for example, aluminum. The gas distributor insert 240 can be made by machining from a monolithic block.

The gas distributor insert 240 has a plurality of radial slots 252 that extend through the insert 240 to allow passage of process gas therethrough. The slots 252 are spaced apart from one another and arranged in a radial configuration. For example, in one version, the gas distributor insert 240 has from about 5 about 50 slots 252, for example about 20 slots 252. In one version, each slot 252 has a length of from about 0.4 to about 1.2 inches, and a width of from about 0.01 to about 0.05 inches. Each slot 252 is oriented in the annular plate of the insert 240 to have a predefined radially or circumferential angle. The slots 252 are angled through the plate and have a uniform pitch. The slots 252 are arranged in this manner to maintain a vortex flow of the process gas through the gas distributor insert 240. The pitch of the slots 252 is chosen to optimize the vortex flow through the slots 252 and is between about 20 and about 70 degrees, or more typically about 45 degrees. The radially angled slots 252 distribute the process gas above the substrate 24 to provide a uniform thickness of gas molecules adsorbed to the processing surface of the substrate 24.

In one embodiment the gas distributor insert 240 has a plurality of cylindrical channels 246 that extend through the insert 240 about the center of the insert 240 to allow passage of process gas therethrough. The channels 246 can comprise between 5 and 20 channels and in one version comprise 12 channels. The channels 246 begin about the base of the protrusion 244 and terminate at the underside of the insert 240. The cylindrical channels 246 are arranged in a circular symmetric configuration about the base of the protrusion 244 and are tilted inwards such that the channels terminate at a position that is located below the protrusion 244. In one embodiment the channels 246 are angled at between 30 and 60 degrees to the vertical axis. The angled channels 246 deliver process gas to the central region of the substrate surface and provide uniform deposition on the substrate. The diameter of the cylindrical channels 246 is from about 0.01 to about 0.1 inches and in one version the diameter of the upper end of the channels 246 is greater than the diameter of the lower terminus of the channels 246. This provides a reduction in back flow within the channels 246.

In this embodiment, the process gas introduced into the chamber 22 is energized by a gas energizer that couples energy to the process gas in the process zone 34a of the chamber 22a. For example, the gas energizer may comprise process electrodes that may be electrically biased to energize the process gas; an antenna comprising an inductor coil which has a circular symmetry about the center of the chamber 22a; or a microwave source and waveguide to activate the process gas by microwave energy in a remote zone upstream from the chamber 22a.

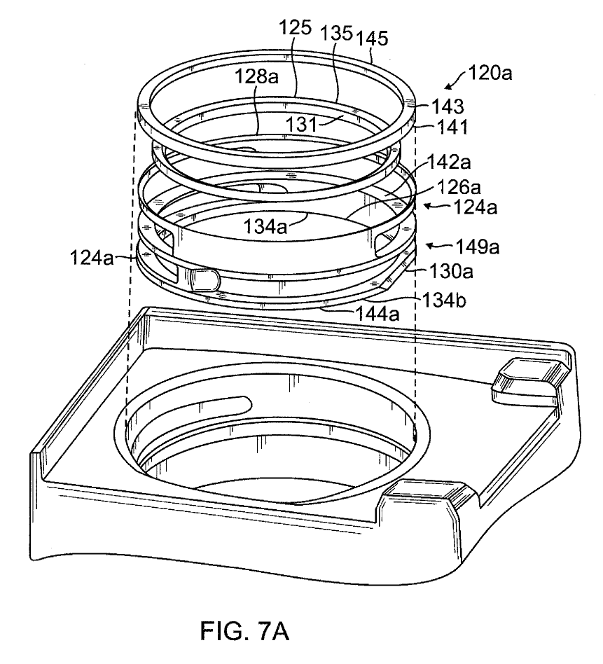

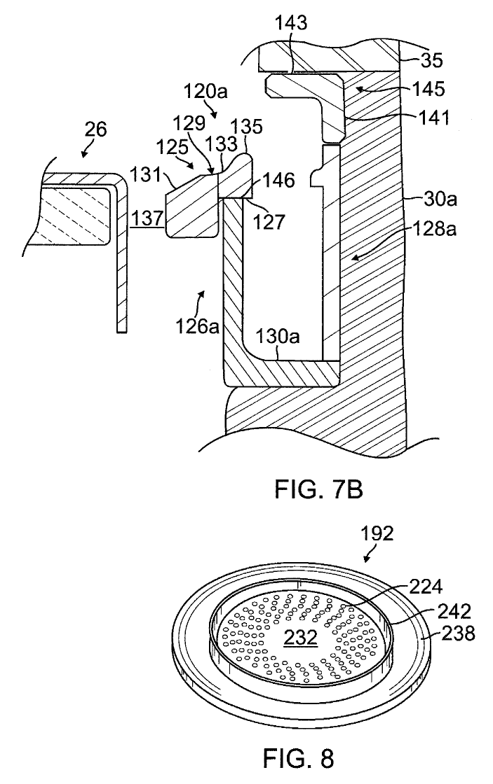

A chamber liner 120a suitable for use in plasma ALD chamber 22a is shown in FIG. 7A. This version of the chamber liner 120a also covers a sidewall 30a of the chamber 22a to encircle the process zone 34a and shield the walls of the chamber 22a from the process gas. The chamber liner 120a is made partially of a ceramic material, such as aluminum oxide (Al₂O₃)or aluminum nitride (AlN), and partially of a metal, such as aluminum or stainless steel. The chamber liner 120a comprises first annular band 126a having a first diameter and a second annular band 128a having a second diameter that is larger than diameter of the first annular band 126a, as shown in FIG. 7A. For example, the second diameter of the second annular band 128a can be at least about 1 cm larger than the first diameter of the first annular band 126a. The first annular band 126a also comprises a first height and the second annular band 128a comprises a second height that is at least 0.5 cm larger than the first height of the first annular band 126a. The first and second annular bands 126a,128a of the chamber liner 120a are joined at their bottom edges 134a,b by a radial flange 130a which is circular in shape and a radial ledge 136a further joins the midsection 138a of the second annular band 128a to the top edge 140a of the first annular band 126a of the chamber liner 120a.

The chamber liner 120a also has a first encased opening 139a which allows process gas to flow through the first and second annular bands 126a, 128a from the process zone 34a to the exhaust port 52a. The first opening 139a is formed by the alignment of a first slot 146a extending therethrough the first annular band 126a and a second slot 146b passing through the second annular band 128a which is aligned to the first slot 146a of the first annular band 126a. The aligned slots 146a,b are surrounded by a flat top wall 142a and bottom wall 144a to form an encased first opening 139a. In one version, the first and second slots 146a,b comprise rectangles with rounded corners. For example, the rectangles can each have a length of from about 12 to 18 inches and a height of from about 0.75 to 3 inches. The chamber liner 120a also has a second opening 149a in the first annular band 126a which opens to the exhaust port 52a. The second opening 149a comprises a rectangle having rounded corners, and which has a length of from about 5 to 9 inches and a height of from about 0.75 to 3 inches. The first and second openings 139a, 149a facilitate the passage of gas through the chamber liner 120a.

The chamber liner 120a additionally comprises a profiled inner shield ring 125 and an upper shield ring 145. Referring to FIG. 7A and FIG. 7B the inner shield ring 125 has a diameter sized to encircle the substrate support 26 that faces the gas distributor 40a in the ALD chamber 22a. The inner shield ring 125 serves as a partial physical barrier for the gasses in the process zone 34a. The inner shield ring 125 comprises a band having an upper, outwardly extending support lip 127. The support lip 127 of the inner shield ring 125 rests on the top edge 146a of the first annular band 126a of the chamber liner 120a.

The upper surface 129 of the band is contoured such that a peripheral region is higher than a radially inner region. The upper surface 129 comprises an inward angled portion 131, a middle horizontal portion 133, and an outer hump portion 135. To minimize turbulence, these regions of the upper surface 129 are connected by smooth corners. The hump portion 133 is situated above the outwardly extending lip 127 and has a height that is higher than the height of the periphery of the substrate support assembly by from about 0.01 to about 0.5 inches. The hump portion 133 serves as a barrier to deter outward radial flow of the activated process gasses from the process region 38a.

The radially inner region of the inner shield ring 125 extends inward from the first annular band 126a by from about 0.2 to about 0.7 inches and defines one side of a gap 137 between the substrate support 26 and the chamber liner 120a. The edges of the inner shield ring and of the substrate support assembly are rounded about the gap 137 to decrease turbulence of the process gas during chamber purge steps. The decrease in turbulence provides a decrease in flow resistance, and allows for a more effective purge step.

An upper shield ring 145 rests on the upper surface of the second band 128a. The upper shield ring 145 shields an upper portion of the chamber sidewall 30a and a peripheral portion of the ceiling assembly from the active gasses of the process zone 34a, to reduce deposition of process gasses on and etching of the chamber body. The upper shield ring 145 comprises an outer cylindrical band 141 capped by an inwardly extending ledge 143. The ledge 143 extends radially inward from the band 141 by from about 0.25 to about 1 inch. The upper shield ring 145 comprises a ceramic and has a thickness of from about 0.25 to about 1 inch.

The ALD chambers 22, 22a and their components described herein significantly improve the thickness and compositional conformity of the atomic layer deposited onto a substrate 24. For example, the gas distributor 40 structure provides a rapidly flowing vortex of gas molecules that more rapidly passes over the substrate 24 surface to provide better and more uniform gas adsorption on the substrate 24 surface. Also the gas vortex prevents the formation of gas molecule stagnation regions in the chamber 22. Further, atomic layer deposition is more uniform when the pressure of the reactant gas at the surface of the substrate 24 is uniform. The present gas distributor 40 provides much better gas pressures across the substrate 24 surface to provide a more uniform thickness of the deposited ALD layer across the substrate 24.

The chamber liner 120 and exhaust shield assembly 160 components also assist in the ALD process by allowing rapid withdrawal of gas species from the chamber 22. This allows fresh gas molecules to adhere to the substrate 24 surface. Rapid withdrawal of the gas species enables the ALD chamber 22 to be effectively and efficiently purged between process gas steps. Further, when the process gas includes organic molecules or reactant gasses which have higher decay rates, the time between introduction of process gas, and hence the time required for an effective purge of the chamber 22, is an important process parameter. Moreover, because the chamber liner 120 and exhaust shield components can be readily disassembled and removed from the chamber 22, it reduces the chamber 22 downtime that would otherwise be required for cleaning or replacing these components.

The present invention has been described with reference to certain preferred versions thereof; however, other versions are possible. For example, the exhaust liner or components thereof and the chamber liners 120, 120a can be used in other types of applications, as would be apparent to one of ordinary skill, for example, etching, CVD and PVD chambers. Also, the shapes of the flanges of the various components can be different, to interface with different chamber flanges and support walls. Also, the materials of composition of the various components can be different for different applications such as composite ceramic or even fully ceramic materials for application in plasma excitation or hybrid etch processes. Therefore, the spirit and scope of the appended claims should not be limited to the description of the preferred versions contained herein.

What is claimed is:

1. An atomic layer deposition chamber comprising:
(a) a sidewall surrounding a bottom wall;
(b) a substrate support extending through the bottom wall;
(c) a gas distributor comprising:
(i) a central cap comprising at least one gas inlet, a gas outlet, and a conical passageway between the gas inlet and gas outlet; and
(ii) a ceiling plate comprising a first conical aperture that receives a process gas from the gas outlet of the central cap, a second conical aperture extending radially outwardly from the first conical aperture, and a peripheral ledge that rests on the sidewall of the chamber; and
(d) an exhaust port to exhaust the process gas from the process zone.

2. A chamber according to claim 1 wherein the conical passageway of the central cap comprises first and second diameters, and wherein the first diameter is less than about 2.6 cm and the second diameter is at least about 3 cm.

3. A chamber according to claim 2 wherein the first diameter is from about 0.2 to about 2.6 cm and the second diameter is from about 3 to about 7.5 cm.

4. A chamber according to claim 1 wherein the conical passageway comprises a conical surface that is inclined from the vertical at an angle of from about 20° to about 25°.

5. A chamber according to claim 1 wherein the central cap comprises a plurality of gas inlets that are offset.

6. A chamber according to claim 4 wherein the gas inlets are offset from one another by being spaced apart along a horizontal plane.

7. A chamber according to claim 4 wherein the gas inlets are offset from one another by being positioned at a separation angle of at least about 45 degrees.

8. A chamber according to claim 1 wherein the first and second conical apertures of the ceiling plate comprise conical surfaces with different inclination angles.

9. A chamber according to claim 7 wherein the first conical aperture comprises a conical surface having an inclination angle of from about 20° to about 25°, and the second conical aperture comprises a conical surface having an inclination angle of from about 3° to about 5°.

10. A chamber according to claim 1 further comprising a fluid conduit about the central cap and ceiling plate, the fluid conduit provided for passing heat transfer fluid therethrough.

11. A chamber according to claim 10 wherein the fluid conduit comprises a channel that is machined into the ceiling plate.

12. A chamber according to claim 10 wherein the fluid conduit is rectangular.

13. A chamber according to claim 1 wherein the cap is composed of a ceramic.

14. A chamber according to claim 1 wherein the ceiling plate is composed of a ceramic.

15. An atomic layer deposition chamber comprising:
(a) a sidewall around a process zone;
(b) a substrate support capable of receiving a substrate in the process zone;
(c) a chamber liner encircling the process zone, the chamber liner comprising
(i) a first annular band having a first diameter and a first slot extending therethrough;
(ii) a second annular band having a second diameter that is sized larger than diameter of the first annular band, and having a second slot aligned to the first slot of the first annular band; and
(iii) a radial flange joining the first and second annular bands;
(d) a gas distributor to introduce a process gas into the process zone; and
(e) an exhaust to exhaust the process gas.

16. A chamber according to claim 15 wherein the first and second slots both comprise rectangles with rounded corners.

17. A chamber according to claim 16 wherein the rectangles each have a length of from about 12 to 18 inches.

18. A chamber according to claim 16 wherein the rectangles each have a height of from about 0.75 to 3 inches.

19. A chamber according to claim 15 wherein the first and second annular bands comprise bottom edges, and wherein the radial flange joins the bottom edges.

20. A chamber according to claim 15 wherein the first and second annular bands comprise midsections, and wherein the chamber liner further comprises a radial ledge that joins the midsections.

21. An apparatus according to claim 15 wherein the first annular band comprises a first height and the second annular band comprises a second height that is larger than the first height.

22. An apparatus according to claim 15 wherein the chamber liner is composed of aluminum.

23. An exhaust shield assembly for an atomic layer deposition chamber, the assembly comprising:
(a) an inner shield comprising an enclosed rectangular band having a perimeter, and a planar frame extending perpendicularly beyond the perimeter of the rectangular band;
(b) a pocket shield comprising (i) a tubular encasing having a top end, an inner rectangular cutout that fits the rectangular band of the inner shield, and an outer circular cutout, and (ii) a cover to cover the top end of the tubular encasing; and
(c) an outer shield comprising (i) first and second cylinders that are joined to one another, the first cylinder sized larger than the second cylinder, and (ii) a planar member attached to the second cylinder and extending perpendicularly beyond the second cylinder.

24. An assembly according to claim 23 wherein the substrate processing chamber comprises a hollow exhaust block having inner and outer walls and a round outlet port, and wherein the pocket shield is sized to fit inside the hollow exhaust block.

25. An assembly according to claim 24 wherein the inner shield is adapted to be positioned on an inner wall of the hollow exhaust block and the enclosed rectangular band is sized to fit over a rectangular inlet port of the hollow exhaust block.

26. An assembly according to claim 24 wherein the outer shield is adapted to be positioned on an outer wall of the hollow exhaust block and second cylinder of the outer shield is sized to fit the round outlet port of the hollow exhaust block.

27. An assembly according to claim 23 wherein the inner shield, pocket shield, and outer shield, are composed of aluminum.

28. An assembly according to claim 23 wherein at least one of the inner shield, pocket shield, and outer shield, comprise a bead-blasted surface.

29. An assembly according to claim 28 wherein the bead-blasted surface has a surface roughness of about 50 to about 62 microinches.

30. A lid assembly for a substrate processing chamber, the lid assembly comprising:
(a) a chamber lid having a bottom surface;
(b) a showerhead that fits in the bottom surface of the chamber lid, the showerhead comprising a central hole; and
(c) a gas distributor insert to fit into the central hole of the showerhead, the insert having a plurality of radial slots that are spaced apart from one another.

31. An assembly according to claim 30 wherein the showerhead has from about 500 to about 2500 holes.

32. An assembly according to claim 30 wherein the insert is composed of aluminum.

33. An assembly according to claim 30 wherein the insert comprises radial slots numbering from about 5 to about 50.

34. An assembly according to claim 30 wherein each radial slot has a width of from about 0.01 to about 0.05 inches.

35. An assembly according to claim 30 wherein each radial slot has a length of from about 0.4 to about 1.2 inches.

36. An assembly according to claim 30 wherein each radial slot is angled at least about 30°.
